(19) United States
(12) Patent Application Publication
(10) Pub. No.: US 2005/0205898 A1
(43) Pub. Date: Sep. 22, 2005

(54) Electronic imaging device

(75) Inventors: Anton Petrus Maria Van Arendonk, Eindhoven (NL); Arjen Gerben Sijde, Eindhoven (NL); Leendert Bruin, Eindhoven (NL); Walterus Theodorus Franciscus Maria De Laat, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKIJKLE PHILLIPS ELECTRONICS N.V.

(21) Appl. No.: 10/515,750

(22) PCT Filed: Apr. 25, 2003
(86) PCT No.: PCT/IB03/01717

§ 371 Date: Nov. 24, 2004

(51) Int. Cl. H01L 29/768

(52) U.S. Cl. 257/222

(57) ABSTRACT

An electronic imaging device (10) comprises a base layer (20) containing electrical functional circuitry, the base layer (20) having a first side (22) for interconnection of the circuitry and a second side (24) which serves as a photo-detection side. The second side (24) has exposed photosensitive electrical elements arranged in the base layer (20). Spacer means of a predetermined height are provided adjacent to said second side (24). This spacer means can advantageously be used for gaining control over the tolerance of a desired distance between a lens of a lens system and said photo-detection side. Thus, individual focusing of the lens system of each imager device after completion of production is no longer needed. Moreover, in one embodiment of the present invention an air gap that improves the performance of micro-lenses is formed.

The invention relates to an electronic imaging device according to claim 1, in particular to an electronic imaging chip.

Today's developments in image sensor technology are paving the way for a new generation of digital imaging products with broad consumer applicability. According to research studies, consumer's first preference for a computer peripheral is a digital camera. Digital camera sales have continued to boom since this high-quality, full-featured product became affordable for a large section of consumers. Considering the possibility to provide instantly viewable images which can also be easily inserted into computer-generated documents, the rise in the popularity of the Internet as a communications medium and, most importantly, the elimination of the cost and time of film processing, digital cameras are going to replace traditional film cameras for many consumer applications. The total available market for digital imaging, including industrial and security cameras, medical appliances, automotive sensors, PC videocams, scanners, digital still cameras and digital camcorders is forecast to grow from about 20 million units in 1996 to over 100 million units in 2002. Therefore, tough competition in the market demands more efficient and rationalized production of image sensor devices for the mass consumer market.

First of all, imaging devices, also called image sensors or simply imagers, are specialized integrated circuits that act as the eye of electronic equipment. Thereby, they detect and convert incident light, i.e. photons, first into an electronic charge, i.e. electrons, and ultimately into digital bits, i.e. binary information. Each individual picture element (pixel) corresponds to a solid-state photosensitive sensor element. Typically, an image sensor comprises at least one array of such sensor elements, e.g. in scanners. Usually, these sensor elements are arranged as a two-dimensional matrix forming an image plane, e.g. in digital still or video cameras. The side of the chip containing the sensor elements, which functions as the light-sensitive area, is also called the photosite or photo-detection side. For such sensor elements, two main technologies are used: the Charge-Coupled Device (CCD) technology and the Complementary Metal Oxide Semiconductor (CMOS) technology.

The simplest CCD image sensor element imaging one pixel is a charge transfer device that collects photocharge in pixels and uses clock pulses to shift the charge along a chain of pixels to a charge-sensitive amplifier. CCDs output pixel-by-pixel analog signals. The simplest CMOS image sensor element imaging one pixel is a so-called passive pixel which consists of a photodiode and an access transistor. The photo-generated charge within the photodiode is passively transferred from each pixel to downstream circuits.

Silicon, although ideal for making active devices, exhibits poor high frequency properties due to its semiconductor nature. This results in poor interconnects and cross-talk and prevents the integration of high-quality strip lines and inductors. Based on a revolutionary bipolar process, the Silicon-On-Insulator (SOI) technology is a novel approach enabling circuits to be transferred to a range of insulating substrates. The advantage of using an insulator over silicon is that parasitic capacitances are reduced. This enables elimination of the problem that in very small structures interconnect capacitances, in particular when using more and more higher frequencies, become dominant in the overall power consumption of the circuit. In a broader approach to SOI, in the so-called Silicon-On-Anything (SOA) technology, these effects can almost entirely be eliminated because the complete circuit is transferred to an insulating substrate such as glass. In principle, the wafer is glued top-down to a new substrate and the original silicon is removed.

Firstly, an important object in imager chip production is the fraction of real estate within each pixel which detects light, i.e. the optical fill factor. Today's fill factors are not 100%, because a part of the pixel area is used to transfer the signal to the rest of the imager circuits. Therefore, the light incident elsewhere is either lost or could give rise to artefacts in the images by generating electrical currents in the circuitry. One known way to increase the fill factor while having the same resolution is the use of micro-lenses, being a standard feature of CCDs and many CMOS active-pixel sensors. Micro-lenses focusing light on each pixel's photosensitive part can be etched directly on the chip's surface for each pixel or added as an individual element during production. Thus, when accurately deposited over each pixel, micro-lenses concentrate the incoming light into the photosensitive region, resulting in an increased effective fill factor.

Secondly, although electronic imaging chips, such as the above CCD and CMOS imagers, have found extensive use in electronic imaging devices, their utilization has often been limited because of size; first no packing technology was available to have an interconnection at the opposite side of the backside of the pixel plane. In the afore-mentioned SOI technology, a possibility would be to etch holes in the glass substrate, but this is not a favorable solution due to the vast amount of processing required, and the a difficulty in achieving the aspect ratio.

U.S. Pat. No. 5,495,114 introduces a method of manufacturing a miniaturized charged-coupled device comprising the steps of shaving a silicon layer to a thinness sufficient to allow passage of a light image therethrough. The CCD is then reversed, so that the image is projected through the shaved silicon layer. Leads are bump-bonded to the former front surface of the CCD, in perpendicular relation thereto, so as to lie within the area defined by the peripheral edge thereof for the supply of electrical signals to and from the CCD.

At the moment, SOA/SOI technology seems to provide possibilities for improvements in the scale of imager modules and also in tolerances that can be achieved. A further target of actual investigations concerns wafer level packing, i.e. concentrating as much as possible steps of imager module production at the wafer scale. Here, the research is aimed at more efficient use of the wafer area needed for a single imager chip, i.e. real estate. This would increase the yield rate of a single wafer with respect to the chip output.

Finally, an important and limiting factor in realizing low cost imager modules is the need to perform individual focusing of the lens after assembly of every single imager module. Furthermore, color filters or micro-lenses applied to the surface of the imager chip's photo detection side need an air gap to take advantage of the light fraction caused by the difference between the refraction of the micro-lens material and the air in the air gap. However, since such air gap is generated during the final manufacture of imager modules, one important problem is the pollution of the photosensitive elements by alien materials.

It is, therefore, an object of the present invention to provide an electronic imaging device, particularly an imager chip, which does not need individual focusing of each imager chip's lens system. Furthermore, it is also an object to improve the manufacture of imager modules when color filter and/or micro-lenses are to be applied. Moreover, the real estate needed for each single imager chip on the wafer should be reduced.

Accordingly, there is provided an electronic imaging device, particularly an electronic imaging chip, which comprises a base layer containing electrical functional circuitry, said base layer having a first side for electrical interconnection of the circuitry and a second side as a photo-detection side, wherein said photo-detection side comprises exposed photosensitive electrical elements arranged in said base layer. This base layer may be a conventional silicon wafer and said photosensitive elements can be exposed by way of an etching process. Furthermore, adjacent to said second side there are arranged spacer means of a predetermined height. Advantageously, the spacer means are formed such that production tolerances of the desired height can be controlled within a predetermined range.

For providing electrical interconnection of the electrical functional circuitry, interface means are arranged on the first side of the silicon base layer. These interface means may be a flex foil. Preferably, the flex foil is a multilayer flex foil. The interface means are attached to connection means for the electrical interconnection of the first side to the interface means. The flex foil may be arranged on the silicon base layer by way of an electrically conductive adhesive. However, the flex foil can also be electrically connected to the electrical circuitry within the silicon base layer by using a compression technique. Both in the case of the conductive adhesive and in the case of the use of a compression technique, predetermined leads of the functional circuitry and predetermined leads of the flex foil are brought into electrical contact. Advantageously, said interface means provide a rigid support that strengthens the thin silicon base layer. Also, the first side of the silicon base layer is protected against direct heat radiation, e.g. infrared radiation.

In a further embodiment of the present invention, the electronic imaging device is provided with color filter means arranged on said photo detection side in the path of the light to said photosensitive electrical elements. Also, it is possible to arrange, additionally to or instead of the color filter means, micro-lenses in the path of the light to said photosensitive electrical elements. For that purpose, the micro-lenses can be arranged on a recessed image area which is formed by a topographical difference within the functional circuitry between the periphery and the image area, i.e. the area containing the photosensitive elements. Therefore, extra metal layers in the periphery could be used to provide a total thickness that is larger than in the image area. In this case, a glass layer can be put on top of the wafer, automatically forming an airgap above the photosite, thus improving the effectiveness of micro-lenses and preventing pollution.

In another alternative, the oxide above the micro-lenses is etched to realize the airgap with more topography. However, since it is desirable to avoid as much as possible sacrificial silicon, a further way of generating the air gap will be discussed hereinbelow for another preferred embodiment in which there is hardly any periphery due to the interconnection possibility on the back of the photo-detection side.

In order to project a light image onto said photo detection side, the electrical imaging device comprises a lens system for focusing a light image on said photosensitive elements. The lens system generally comprises a lens-holder with a lens-barrel containing a lens. Furthermore, said lens system can be made of a moulded resin and may be fixed by way of an adhesive.

In a first embodiment of the invention said lens system comprises spacers of predetermined height. Furthermore, said lens system is arranged on said base layer at said photo detection side with said spacers.

In a second embodiment of the invention said photosite comprises spacers of predetermined height and shape which may be formed by an etching process. Thus, the shape and height of the spacers can be exactly controlled via the etching process by using the thickness and the crystal structure of the silicon. As one possible way described herein, said spacers can be made by applying an oxide pattern on said photo-detection side of said base layer as an etch mask during the etching of said photo detection side of said base layer so as to expose said electrical photosensitive elements. Said silicon spacers make it possible to gain control of the height tolerances such that a process, and hence the final product, is obtained without the need of focusing the lens on each individual imaging device. The total height tolerance that can be achieved, for the process is in the range of ±30 microns, a big part thereby being taken up by the molding tolerances of the lens-holder; therefore, limiting the lens-holder dimensions by using the silicon spacers will be of assistance in satisfying the requirements in respect of tolerances.

Furthermore, it would be advantageous to provide a transparent layer on said silicon spacers. Said transparent layer may be made of a material that allows predetermined frequencies of the light spectrum passing through towards said photo detection side. Preferably, said transparent layer is a glass layer. Furthermore, the lens system can be attached to said transparent layer so as to focus the light image onto said photosensitive elements contained within said photo-detection side. When a glass wafer is provided as a possibly transparent layer on the silicon wafer comprising the single dies containing the circuits with the image sensors, the known advantage of the air gap in front of the micro-lenses can be incorporated in this step of connecting the silicon wafer to the glass wafer. Moreover, the glass wafer supports the silicon device with additional strength.

Another advantage of the transparent layer is that the photosensitive elements are sealed air-tight during manufacture in a clean atmosphere. Furthermore, the final module can be reflowed without the optical lens like land grid array (LGA) packages due to the limited temperature range of the lens and the lens-holder. It may also be attached to a printed circuit board (PCB), together with the optical lens system, when a conductive pressure sensitive adhesive is used, deformation of the lens system by heat during the reflowing process thus being avoided. Finally, the lens system attached directly to the silicon base layer or the transparent layer attached to the silicon spacers form an air-tight cavity which is subject to pressure changes. This could result in bending of the silicon base layer. Therefore, it is a further advantage of the interface means that they provide a rigid support which prevents the silicon base layer from bending.

The manufacture of the described electronic imaging device comprises the step of generating said base layer by a Silicon On Anything (SOA) process. Moreover, according to the present invention the whole electronic imaging device may be manufactured at the wafer level. Therefore, said manufacturing process can be controlled to such an extent that tolerances of ±30 microns are provided in respect of a predetermined distance between said exposed electrical photosensitive elements and said lens within said lens system.

Another advantage of the present invention is the possibility of wafer level packing. Here, the SOA process used also provides new possibilities for optimization in the manufacture of such modules. This also allows the building of smaller imager modules. Therefore, the whole package will be manufactured on a wafer scale, including the lens mount which will also function as a rigid support for the very thin silicon with flex foil on top. The additional effect of using silicon spacers is a mechanical support of the device in addition to the support from the lens-holder.

Generally speaking, a global process flow for manufacturing such an electronic imaging device within a SOA process may comprise the following steps:
a) attaching a multilayer flex foil on the first side of the wafer containing interconnection means of the functional circuitry buried within said wafer by known semiconductor technologies. This may be done with conductive adhesive or other techniques like using bumps with soldering. A compression technique may also be used to provide electrical connection between the functional circuitry and the flex foil;
b) removing silicon from the second side of said wafer, that is, the side opposite to said first side, by etching said silicon wafer; in this respect there will be two possible ways (A) and (B) to proceed:
   A) etching the second side of the wafer only at the location of the image area where the photosensitive elements are placed, so that the remaining part of the silicon can be used as spacers for the lens system. Additionally, in this case, it is possible to put a transparent layer onto said silicon spacers in order to form an air gap between the photo-detection side and said transparent layer and, moreover, to protect the photo-detection side from being polluted by alien materials; or
   B) etching the whole second side of the wafer where separate spacers for the lens system are needed, e.g. by the lens system itself.

Then, according to the foregoing steps (A) and (B):
c) attaching a lens system (lens-holder, lens-barrel and lens), using an adhesive or the like, to said silicon spacers or said transparent layer, i.e. case (A), or directly to said silicon layer using spacers provided by said lens system, i.e. case (B); and
d) singulating the wafer in individual imaging devices, i.e. sensor modules.

Producing the whole imager module at the wafer level not only enables high quality standards to be satisfied, but also a reduction of the manufacturing cost since individual focusing of each imagers chip lens system is no longer required. Focusing is a costly step since the lens system usually has a high tolerance. Furthermore, final testing of the single module at the wafer level is also possible.

The above and other objects, features and advantages of the present invention will become apparent from the following description of the preferred embodiments thereof, given with reference to the accompanying drawings. It should be noted that the same or equivalent parts retain the same number throughout the Figures.

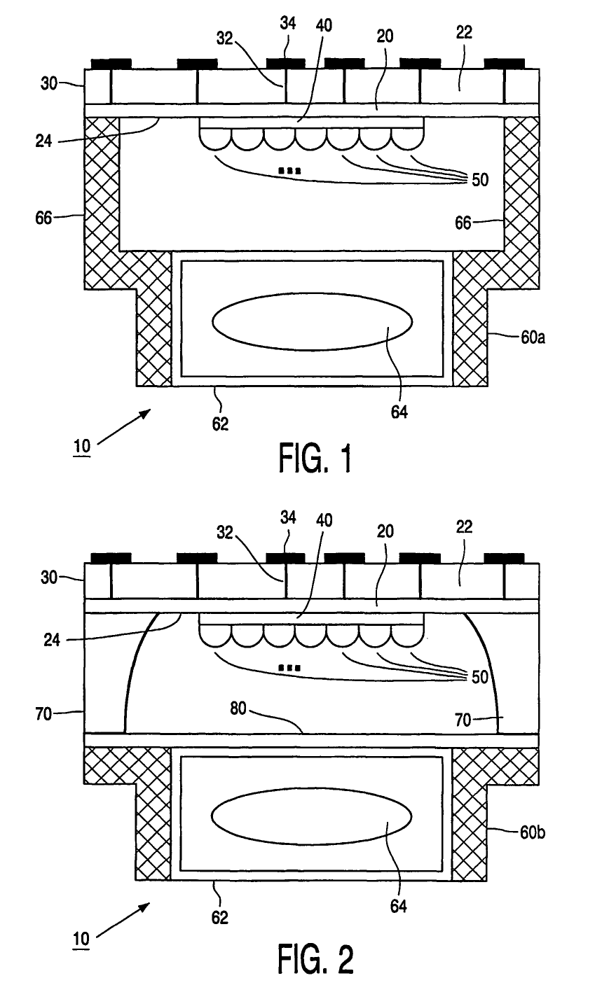

FIG. 1 shows a first embodiment of the invention; and

FIG. 2 shows a second embodiment of the invention, wherein a transparent layer is provided to form an air gap between the image plane and the lens system.

FIG. 1 shows a cross-sectional view of the imaging device 10 according to the present invention. First there is provided a silicon base layer 20 containing a silicon device which comprises known functional circuitry according to electronic imaging technology, i.e. photosensitive elements. This silicon base layer has a first side 22 for interconnection of the circuitry and a second side 24 serving as photo-detection side. To said first side 22 there are attached interconnection means 30 in the form of a flex foil, which provides micro vias 32 electrically connecting functional circuitry (not shown in the Fig.) within said silicon base layer 20 from said first side 22 to connection pads 34. Said interconnection means 30 are fixed to said interconnection side 22 by way of an electrically conductive adhesive. The connection pads 34 are copper islands or the like.

On the second side 24 of said base layer 20 a color filter means 40 is arranged over the elements within said image plane. This color filter means 40 is an optical element selectively allowing passage of predetermined frequencies of the light spectrum. Over said color filter means 40 there are arranged micro-lenses 50. These micro-lenses 50 increase advantageously the effective filling factor of the photosensitive elements within the image plane on said second side 24 of said silicon base layer 20.

Over said arrangement of said color filter means 40 and said micro-lenses 50 there is provided a lens system which comprises a lens-holder 60a with a lens-barrel 62 containing a lens 64. Said lens-holder 60a is arranged to hold said lens 64 within said lens-barrel 62 such as to create a predetermined distance between said lens 64 and the image plane on said second side 24 of said silicon base layer 20. Therefore, spacers 66 of predetermined height are provided by that lens-holder 60a. Said lens holder 60a can be made of resin or a similar material and may be fixed to said silicon base layer 20 by means of an adhesive.

According to the objects of the present invention the embodiment according to FIG. 1 provides a small imaging device wherein, in addition to the advantage of a simple construction, the lens system of the imaging device can be incorporated in a range of distances between the lens 64 and the image plane such that individual focusing of each imaging device 10 is no longer needed at the end of production.

Reference is now made to FIG. 2, but only the differences with respect to the embodiment of FIG. 1 will be highlighted. FIG. 2 illustrates a further embodiment of the present invention by way of a cross-sectional view. First, to provide a more accurately predetermined distance between the lens 64 and the image plane, on said photo-detection side 24 of said silicon base layer 20 there are arranged silicon spacers 70. Onto said spacers 70 there is arranged an additional transparent layer 80, which may be a glass layer, attached to said silicon spacers 70 by means of an adhesive. This transparent layer 80 advantageously forms, together with said silicon spacers 70, an air gap which increases the efficiency of said micro-lenses 50 and also seals the photosensitive area at said photo-detection side.

The silicon spacers 70 are formed during the etching of said photo-detection side 24. The applied etching process can be controlled to such an extent that a desired height of said spacers 70 can be provided by taking into account the thickness of the silicon base layer. Furthermore, the shape of the spacers 70 can be controlled by taking into consideration the crystal structure of the silicon base layer 20. Thus, the isotropic shape of the spacers 70 as indicated in FIG. 2 can also be nicely shaped, e.g. a kind of tapering, if the crystal structure of the silicon is used.

Furthermore, since the lens system of this embodiment does not need spacer means for realizing the predetermined distance between the lens 64 and said photo-detection side 24, there is provided a lens-holder 60b, comprising said lens-barrel 62 and said lens 64. The lens-holder 60b is fixed to the transparent layer 80 in a predetermined location such that the lens provides a desired image on said image plane located at said photo detection side 24.

An advantage of this embodiment of the present invention is that the lens system can be attached to the imaging device 10 at the very end, probably after installing the imaging device 10 onto a PCB or the like. Additionally, there is no need for an individual adjustment of the lens system due to the high tolerances that can be achieved within a range of ±30 microns.

In the light of this disclosure, modifications of the described embodiments as well as other embodiments, all within the scope of the appended claims, will be apparent to persons skilled in the art. Moreover, this invention has been described in detail with reference to the accompanying embodiments thereof, but it will be understood that various other modifications can be effected within the scope of the subject matter of the claims.

In the description above, an electronic imaging device has been introduced that comprises a base layer containing electrical functional circuitry, wherein the base layer has a first side for interconnection of the circuitry and a second side as a photo-detection side. The second side has exposed photosensitive electrical elements arranged in the base layer. Furthermore, spacer means with a predetermined height are provided adjacent said second side. The spacer means can advantageously be used for gaining control over the tolerances of a desired distance between a lens of an lens system and said photo detection side. Thus, individual focusing of the lens system of each imager device after production is no longer needed. Moreover, in one embodiment of the present invention an air gap is formed by applying a transparent layer to said spacer means, thus improving the functioning of micro-lenses.

1. An electronic imaging device, in particular an electronic imaging chip, comprising:
a base layer containing electrical functional circuitry, said base layer having a first side for electrical interconnection of said circuitry and a second side as a photo-detection side, wherein said second side comprises exposed photosensitive electrical elements arranged in said base layer and spacer means of a predetermined height are arranged adjacent to said second side.

2. An electronic imaging device according to claim 1, wherein said photosensitive electronic elements are exposed by means of an etching process.

3. An electronic imaging device according to claim 1, comprising interface means arranged for providing electrical interconnection for said electrical functional circuitry and attached to connection means for electrically interconnecting said first side to said interface means.

4. An electronic imaging device according to claim 3, wherein said interface means are a flex foil or a multilayer flex foil.

5. An electronic imaging device according to claim 3, wherein said connection means are an electrically conductive adhesive.

6. An electronic imaging device according to claim 3, wherein said connection means are arranged for providing electrical connection by compression of said interface layer onto said silicon base layer.

7. A electronic imaging device according to claim 1, wherein on said second side there are arranged color filter means in the path of the light to said photosensitive electrical elements.

8. An electronic imaging device according to claim 1, wherein on said second side there are arranged micro-lenses in the path of the light to said photosensitive electrical elements.

9. A electronic imaging device according to claim 1, wherein a lens system with said spacers of a predetermined height is attached to said second side, one end of said spacers being attached to said base layer.

10. An electronic imaging device according to claim 1, wherein said second side comprises a surface topology that provides said spacers with a predetermined height and a predetermined shape.

11. An electronic imaging device according to claim 10, wherein a transparent layer is attached to said spacers.

12. An electronic imaging device according to claim 11, wherein said transparent layer is a glass layer.

13. An electronic imaging device according to claim 11, wherein a lens system is attached to said transparent layer.

14. An electronic imaging device according to claim 9, wherein said lens system also comprises a lens-holder with a lens-barrel containing a lens.

15. A method for manufacturing an electronic imaging device according to claim 1, wherein said electronic imaging device is formed by means of a Silicon On Anything (SOA) or Silicon On Insulator (SOI) process.

16. A method according to claim 15, comprising the step of forming said whole electronic imaging device at the wafer level.

17. A method for manufacturing a electronic imaging device according to claim 10, comprising the step of forming said spacers by applying an oxide pattern on said photo detection side of said base layer as an etch mask during the etching of said photo-detection side of said base layer so as to expose said electrical photosensitive elements.

18. A method for manufacturing an electronic imaging device according to claim 8, comprising the step of making said lens system of a moulded resin.

19. A method for manufacturing a electronic imaging device according to claim 9, said method being adapted to provide tolerances of ±30 microns in respect of a predetermined distance between said exposed electrical photosensitive elements and said lens within said lens system.
